(19) United States
(12) Patent Application Publication
(10) Pub. No.: US 2010/0188128 A1
(43) Pub. Date: Jul. 29, 2010

(54) Method and Apparatus for Shaping Electronic Pulses

(76) Inventors: Haw-Jyh Liaw, Fremont, CA (US); Shwetabh Yerma, Mountain View, CA (US)

Correspondence Address: STATTLER-SUH PC / NETLOGIC, 60 SOUTH MARKET STREET, SUITE 480, SAN JOSE, CA, 95113, US

(21) Appl. No.: 12/728,150

(22) Filed: Mar. 19, 2010

Related U.S. Application Data
(63) Continuation-in-part of application No. 11/844,836, filed on Aug. 24, 2007.

(51) Int. Cl. H03H 11/26; H04B 3/04

(52) U.S. Cl. 327/290; 333/20

(57) ABSTRACT

An initial pulse signal is split into a first pulse signal and a second pulse signal. The first pulse signal is delayed through a first impedance to generate a first delayed pulse signal. The first impedance attenuates the first delayed pulse signal to generate an attenuated pulse signal. The second pulse signal is delayed through a second impedance to generate a second delayed pulse signal. The first delayed pulse signal and the attenuated pulse signal are combined to generate the two-pulse response signal.

### RELATED APPLICATIONS

This patent application claims benefit and priority to, under 35 U.S.C. §120, and is a continuation-in-part of the United States Patent Application entitled “Methods And Apparatus For Shaping Electronic Pulses,” by inventors named Haw-Jyh Liaw and Shwetabh Verma and having Ser. No. 11/844,836 filed on Aug. 24, 2007, which is expressly incorporated herein by reference.

### BACKGROUND OF THE INVENTION

1. Field of the Invention

The present invention relates to the field of generation of stress pulses for testing electronic receivers, and is more specifically directed to shaping electronic pulses.

2. Art Background

As the demand for better connectivity to the Internet grows, there is an ever-increasing need for greater bandwidth. As such, modern communication systems have been optimized to achieve higher data rates. As the data rates increase, reliable communication becomes difficult for several reasons, including signal integrity constraints. For instance, the channel through which the data is transmitted has limited bandwidth and has other physical impairments, such as dispersion.

Electronic receivers with built-in filtering capability attempt to overcome some of these physical limitations, and have been shown to improve performance. In testing the performance of such receivers under laboratory conditions, there is a need to generate a wide range of artificially distorted pulses. The collection of these ‘stress-test’ pulses should cover the range of channels the receiver is likely to encounter. A generic two-pulse response can be used to model a wide range of channel responses. This can be done by varying the shapes of the two pulses of the two-pulse response, and their relative amplitudes and spacing. Conventional methods of generating such varying stress-test pulses involve the use of multiple complex and/or expensive active components such as, for example, high-speed amplifiers. The use of these additional active components, however, has certain drawbacks.

Accordingly, there is a need to generate variable two pulse responses preferably without the use of expensive active components, such as high-speed off-chip amplifiers. Embodiments of the invention advantageously generate varied two pulse responses without the need for additional active components.

### BRIEF DESCRIPTION OF THE DRAWINGS

The novel features of the invention are set forth in the appended claims. However, for purpose of explanation, several embodiments of the invention are set forth in the following figures.

FIG. 1 illustrates a symmetric stress pulse as defined by IEEE 802.aq.

FIG. 2 illustrates a conventional feed-forward network configured for generating a symmetric stress pulse.

FIG. 3 illustrates a possible runt path that may occur without the use of isolation amplifiers.

FIG. 4A illustrates a circuit for generation of a stress-test pulse according to some embodiments.

FIG. 4B illustrates incident and transmitted (desired and undesired) waves from a second path at a merge node, in accordance with one embodiment.

FIG. 4C illustrates convergent pulses having the same total delay, according to some embodiments.

FIG. 4D illustrates multiple configurable and/or fixed delay paths that are selectable by switching.

FIG. 5 illustrates a two-pulse source, derived from an Ethernet chip, in accordance with some embodiments.

FIG. 6 illustrates a method of shaping electronic pulses, according to some embodiments of the invention.

### DETAILED DESCRIPTION

In the following description, numerous details are set forth for purpose of explanation. However, one of ordinary skill in the art will realize that the invention may be practiced without the use of these specific details. In other instances, well-known structures and devices are shown in block diagram form in order not to obscure the description of the invention with unnecessary detail.

Exemplary Pulse:

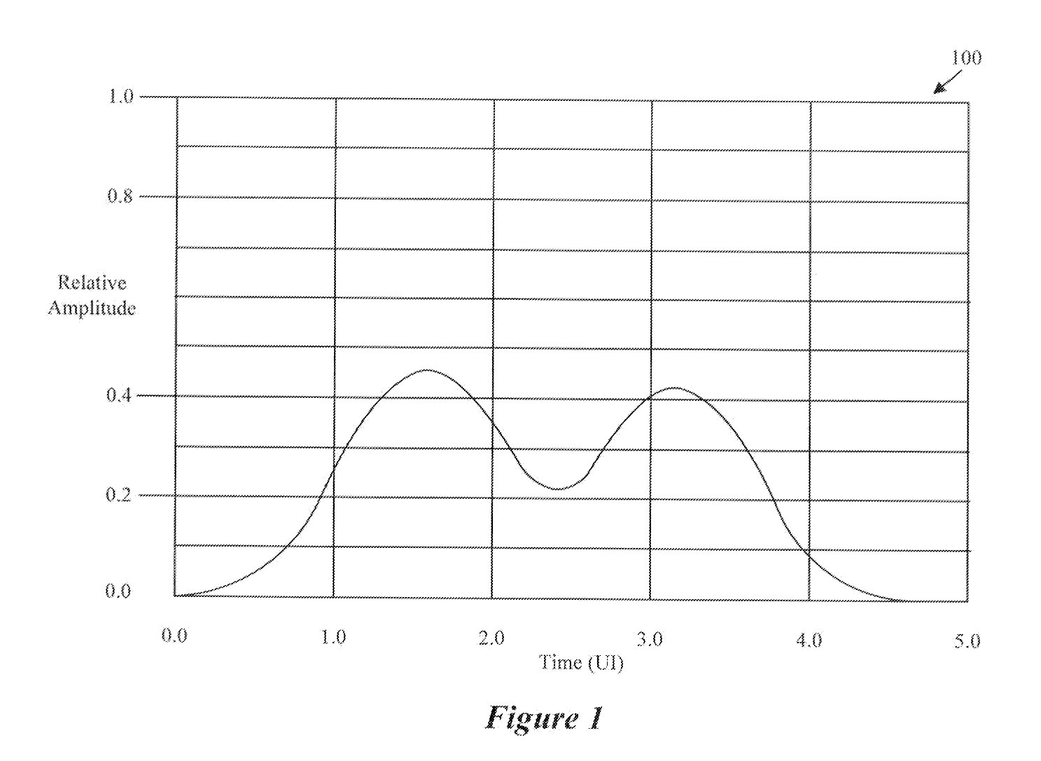

FIG. 1 illustrates an exemplary symmetric stress test pulse 100 as defined by IEEE 802.aq. As recognized by one of ordinary skill, the exemplary pulse 100 is suitable for testing of electronic circuitry, for example. As shown in FIG. 1, the pulse 100 has two peaks each having an amplitude that is shown along they y-axis. The peaks are separated by time, shown along the x-axis. Preferably, other pulses having different shapes are generated for testing over a broad range of parameters. For instance, an alternative test pulse may have different amplitudes and/or different timing (time spacing's) for the peaks of the pulse(s). More specifically, embodiments of the invention are advantageously used for production screening of electronic devices, such as electronic receivers, to determine whether the tested devices meet particular specifications. By using various configurable pulses, further tests are conducted to characterize the device quality. Some embodiments are also integrated into a field device for diagnosing defective receiver modules such as electronic dispersion receivers.

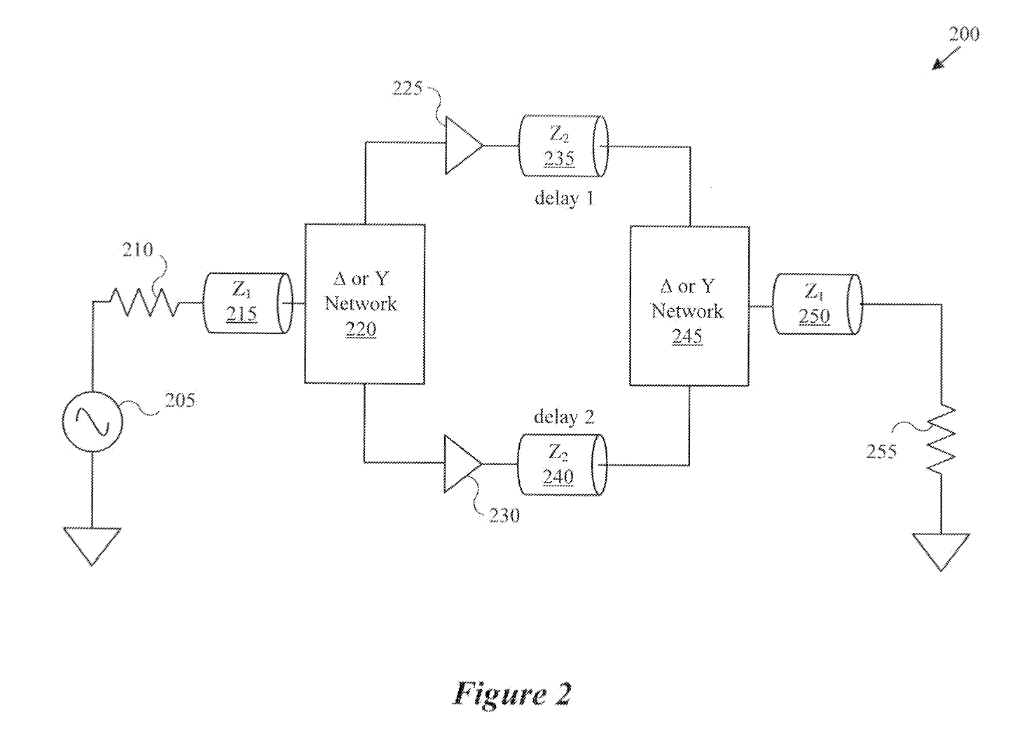

FIG. 2 illustrates a conventional method of generating stress and/or test pulses such as the pulse 100 of FIG. 1. As shown in FIG. 2, a feed-forward network 200 is used to generate the two-pulse response described above. Conventionally, power from a band-limited input source 205 is split into two paths through a matched resistive power splitter/combiner 220 of Δ or Y configuration. The differential delay between the two paths is controlled to generate the proper spacing for the final desired pulse.

The resulting pulses are then buffered by high-speed isolation amplifiers 225 and 230. The high-speed isolation amplifiers 225 and 230 are matched on both ports. These isolation amplifiers 225 and 230 ensure that the path from the input to the output is unidirectional. The amplifiers 225 and 230 also may have different gains to generate different pulse shapes. The buffered pulses are then merged together via another resistive combiner 245 to drive the output. Any returning pulses, which do not go towards the output, are terminated at the outputs of amplifiers 225 and 230. Without amplifiers 225 and 230, signals, which couple from one path into the other, undesirably re-circulate and corrupt the final output signal.

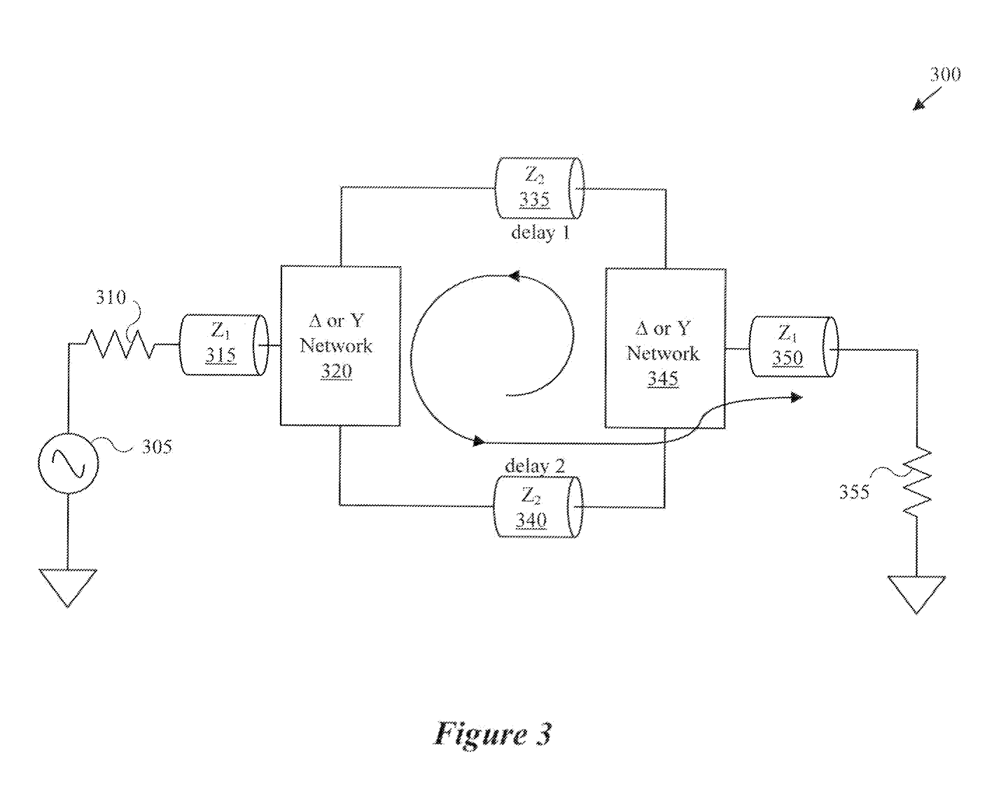

FIG. 3 illustrates a conceptual runt path that may undesirably occur without the isolation amplifiers 225 and 230 of FIG. 2. As shown in FIG. 3, an input source is coupled to a resistor 310 that is coupled to a splitter 320 through a segment 315. The splitter 320 divides a signal such as a pulse received from the input source into two paths, a first path and a second path. The splitter 320 is preferably implemented by using a Δ or Y network that performs the functions of a matched resistive splitter and/or combiner. The first path includes a segment 335 that is coupled to a combiner 345. The combiner 345 is preferably implemented by using a Δ or Y network that performs the functions of a matched resistive splitter and/or combiner. The first path lacks the isolation buffer 225 of FIG. 2.

The second path includes a segment 340 that is coupled to the combiner 345. The second path lacks the isolation buffer 230 of FIG. 2. An output of the combiner 345 is coupled to a segment 350, which is coupled to a resistor 355. In some embodiments, the segments 315, 335, 340, and 350 have impedances of 50 Ohms each.

Also shown in FIG. 3, without the isolation buffers 225 and 230 of FIG. 2, a signal from the second path undesirably re-circulates into the first path, and vice-versa, a signal from the first path may undesirably re-circulate into the second path.

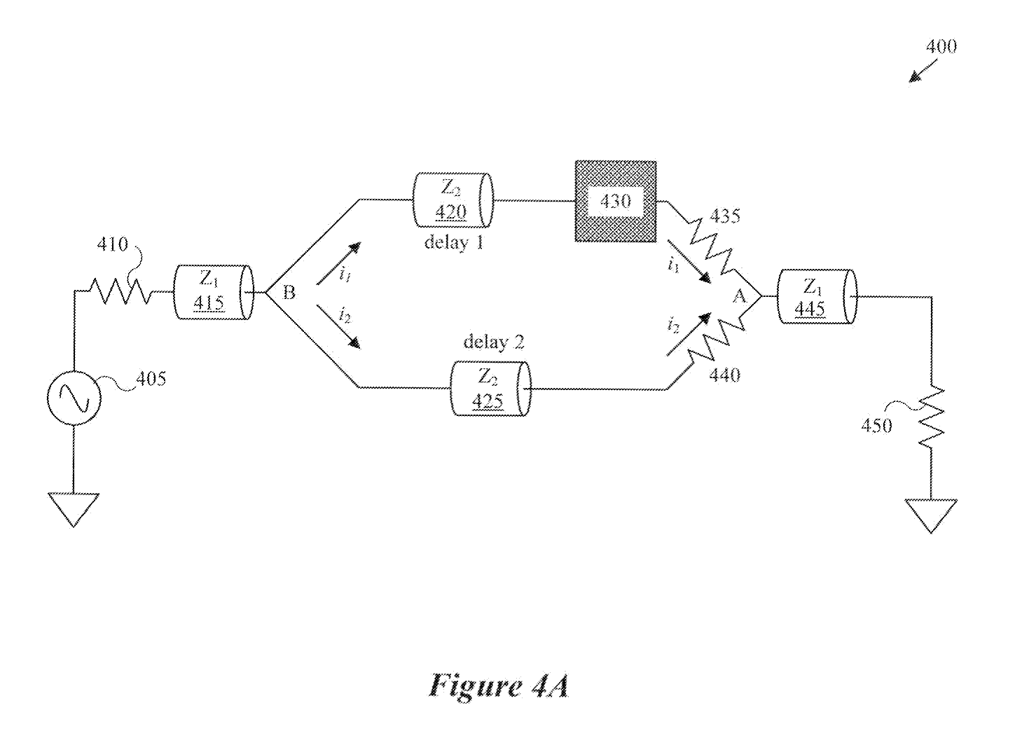

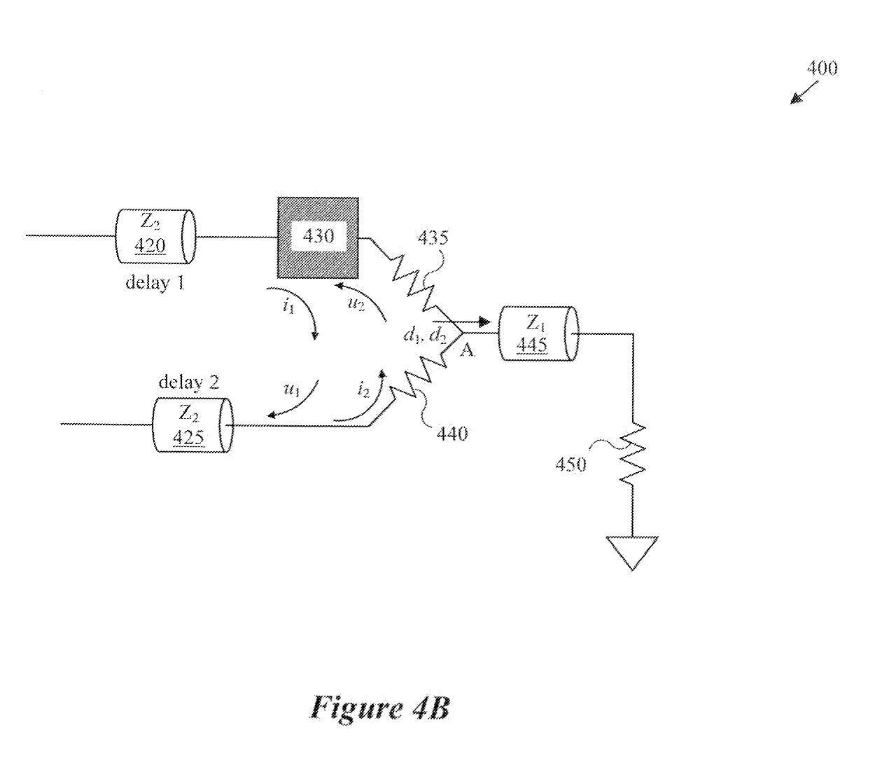

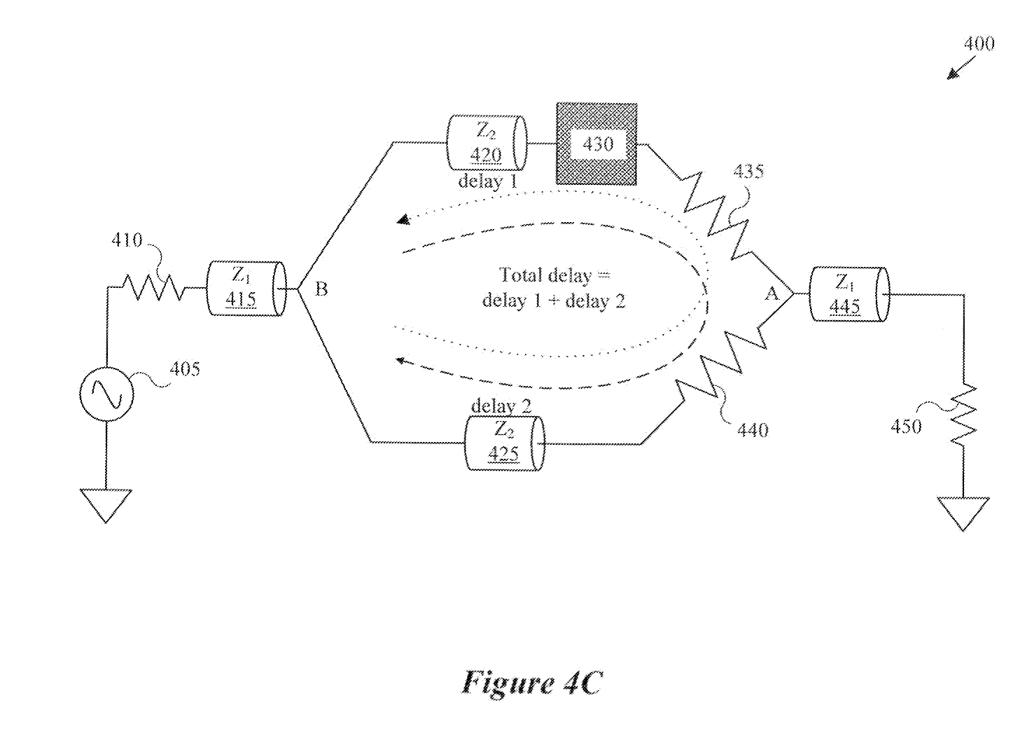

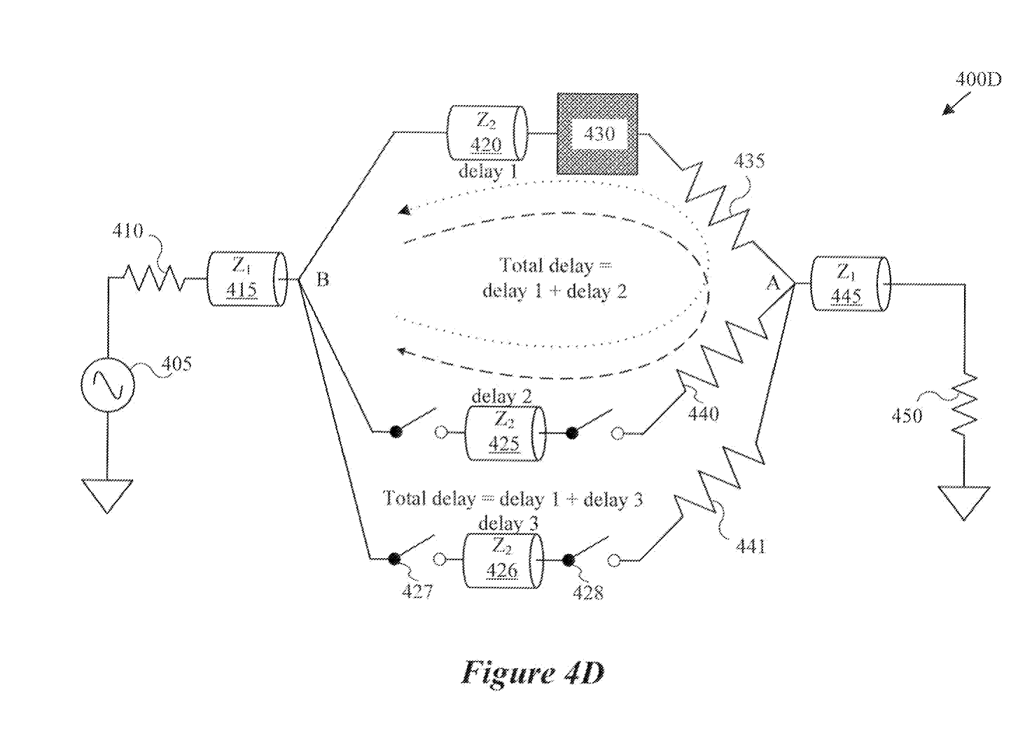

FIGS. 4A, 4B, and 4C illustrate systems for generation of stress and/or test pulses that use a pulse cancellation technique to remove the runt pulses without the need for several complex and/or expensive active components, according to some embodiments.

More specifically, FIG. 4A illustrates a power splitter and combiner configuration 400. As shown in FIG. 4A, a power source 405 generates an initial pulse. The power source 405 may include any number of voltage sources, such as a driver, for example. The initial pulse passes through a resistor 410 and a module and/or segment 415 that has an impedance. In some embodiments, the impedance is given by Z1. The initial pulse is then split or divided at a first node ‘B’ along a first path (top) and a second path (bottom) of the network 400. The initial pulse is preferably divided into a first pulse (i1) for the first path and a second pulse (i2) for the second path, without any reflections of the divided pulses (i1 and i2). The first path has a module and/or segment 420 that has an impedance and a delay, and the second path has a modules and/or segment 425 that has an impedance and a delay. In some embodiments, the impedances of the segments 420 and 425 are given by Z2. In one implementation, the transmission lines (including the modules and/or segments) in the first and second paths are designed to have different delays, Delay 1 and Delay 2, respectively. In these embodiments, varying the difference in the Delay 1 and the Delay 2, adjusts the shape of the output such as the spacing of the peaks of the pulse(s). The delays are configured by a variety of means such as, for example, by selecting the material and/or the length of the modules and/or segments that comprise the transmission lines.

Moreover, the first or upper path utilizes an attenuator 430 to reduce the relative amplitude of the first pulse by a predetermined amount. Since the attenuator 430 controls the amplitude of the first pulse, the relative amplitudes of the two pulses (peaks) of the two-pulse response are set by the attenuator 430. Preferably, the attenuator 430 is matched and/or passive. For instance, the ports of the attenuator 430 are matched to a first characteristic impedance of the first path. Preferably, the matched attenuator 430 is designed to have identical bidirectional gain, and in one embodiment, the attenuator 430 is matched at its input and its output to the impedances of the segments 420 and 425, which in this case, are given by Z2. In a particular case, the impedances of the matched attenuator 430, and the segments 420 and 425, are approximately 100Ω each.

In operation, a first divided pulse from the first path and a second divided pulse from the second path arrive at the merge node ‘A’ at different times. The first and second divided pulses are generated by dividing the initial or input pulse at the node ‘B’. As mentioned above, the spacing of the two-pulse response is shaped by the difference between the total time delay associated with the first path and the total time delay associated with the second path. A resistor 435 in the first path couples the output of the attenuator 430 to the node ‘A’. A resistor 440 in the second path couples the segment 425 to the node ‘A’. Hence, at the node ‘A’ the first pulse from the first path and the second pulse from the second path are combined and provided to an output segment 445. The resistive elements 435 and 440 for each path, coupled at the node ‘A’, are also matched to ensure that there are no reflections from the incident pulses i₁ and/or i₂, as illustrated in FIG. 4B. At the node ‘A’ the forward-going desired pulse(s) d₁ and/or d₂ are launched in the direction of the output segment 445, as illustrated in FIG. 4B. At an output of the output/combiner node ‘A’, the output segment 445 is coupled to a load 450.

Also shown in FIG. 4B, an undesired pulse u₂ may travel back through the first path, while an undesired pulse u₁ may also travel through the second path. Due to the matched impedances and delays of the first and second paths, however, any undesired pulses traveling backward through these paths, are configured to offset each other at the node ‘B’. More specifically, in some implementations, the first and second characteristic impedances of the first and second paths are each substantially equal to twice the source impedance. For instance, where the source impedance and the output impedance (illustrated in the FIG. 4A as Z1) are about 50Ω, the first and second characteristic impedances in the first and second paths (illustrated in the FIG. 4A as Z2) are approximately 100Ω each. In this implementation, the resistive elements 435 and 440 at the merge node ‘A’ are advantageously configured to have impedances of about 62Ω each, which reduces and/or prevents undesirable reflections of the pulse(s). Preferably, the resistive values are calculated based on the impedance values of the various segments and/or paths. In some embodiments, for instance, the values of the resistive elements 435 and 440 are obtained from the following equation:

(Z2+X)//Z1+X=100 where X//Y=(X*Y)(X+Y); and

wherein Z2 represents the characteristic impedance of the first and second path (paths 1 and 2), Z1 represents the characteristic impedance of the output path, and X is the variable for the value of the resistive element. In an embodiment described above, Z2=100Ω, Z1=50Ω, and thus X=62Ω.

Therefore, the first and second paths each launch a pulse such as, for example, a first desired pulse d₁, and a second desired pulse d₂ in FIG. 4B that is slightly delayed, towards the load 450, thereby generating a generic two-pulse shape. Any undesired pulses u₁ and u₂, however, are canceled out at the node ‘B’. In a preferred embodiment, the undesired pulses u₁ and u₂ re-converge at the node ‘B’ at the same instant, since both undesired pulses u₁ and u₂, travel through the first and second paths that are configured to have the same overall path delay.

FIG. 4C illustrates such an embodiment 400 wherein convergent pulses have the same total delay. Any delay through the passive attenuator 430 is absorbed into the impedance 420 that is configured to have the impedance Z1 and the Delay 1. Also, the convergent pulses have the same amplitude, since both pulses travel through the same overall path that includes both the first and second paths. The impedance arrangement at the node ‘B’ allows the merging together of two identical waves, traveling on the segments 420 and 425, onto the segment 445, without any reflections.

In some embodiments, the impedances of the segments 420 and 425 are about 100Ω each, and the segment 445 has an impedance of about 50Ω. In these embodiments, there are no net reflected pulses, and a single, combined pulse is launched towards the source 405. This combined pulse advantageously terminates on its source resistor 410. If there is a mismatch, however, between the amplitude and arrival time of the convergent pulses, undesirable reflections may occur. These undesired reflected pulses may then ripple to the output. In this particular implementation, if the output is not matched to 50Ω, an additional passive attenuator is preferably inserted between the node ‘A,’ and the load resistor 450, which in this case is 50Ω.

One advantage of the embodiments described above is controllability. The entire apparatus 400 is optionally implemented on a printed circuit board, with controlled delays in the first and second (upper and lower) paths. In these cases, controlling the relative delays between the two paths is critical to generate the desired pulse shape. In contrast, the delay from the source stimulus to the node ‘B’ is not relevant, and does not require control. Similarly, the delay from the node ‘A’ to the load 450 does not require control.

In some embodiments, a programmable passive attenuator is advantageously used to attenuate the pulse of one path relative to the pulse of the other path to generate a time-varying shape for the resultant output pulse. Alternatively, or in conjunction with these embodiments, some implementations dynamically change the relative delays between the two paths to further generate and/or control the shape of the resultant pulse. Alternatively, additional fixed delay paths are added between the nodes ‘B’ and ‘A’, and enabled and/or disabled via switches. FIG. 4D illustrates such an embodiment 400D. A shown in FIG. 4D, the systems of FIGS. 4A, 4B, and 4C, further include a third path that has a segment 426 and a resistor 441. The segment 426 has a third configurable delay (Delay 3), and is selectively enabled by using a pair of switches 427 and 428 located on both sides of the segment 426 (and the Delay 3). The pair of switches 427 and 428 reduces and/or eliminates undesirable reflections caused by the presence of the Delay 3 when the path through the segment 426 is not selected, by completely disconnecting the segment 426. One of ordinary skill recognizes that the third path is exemplary, and that any number of additional fixed paths may be included between the nodes ‘B’ and ‘A’. The fixed and/or adjustable paths preferably include configurable delay(s) and are selectively enabled by switches. In these embodiments, only any two paths may be active at a given time.

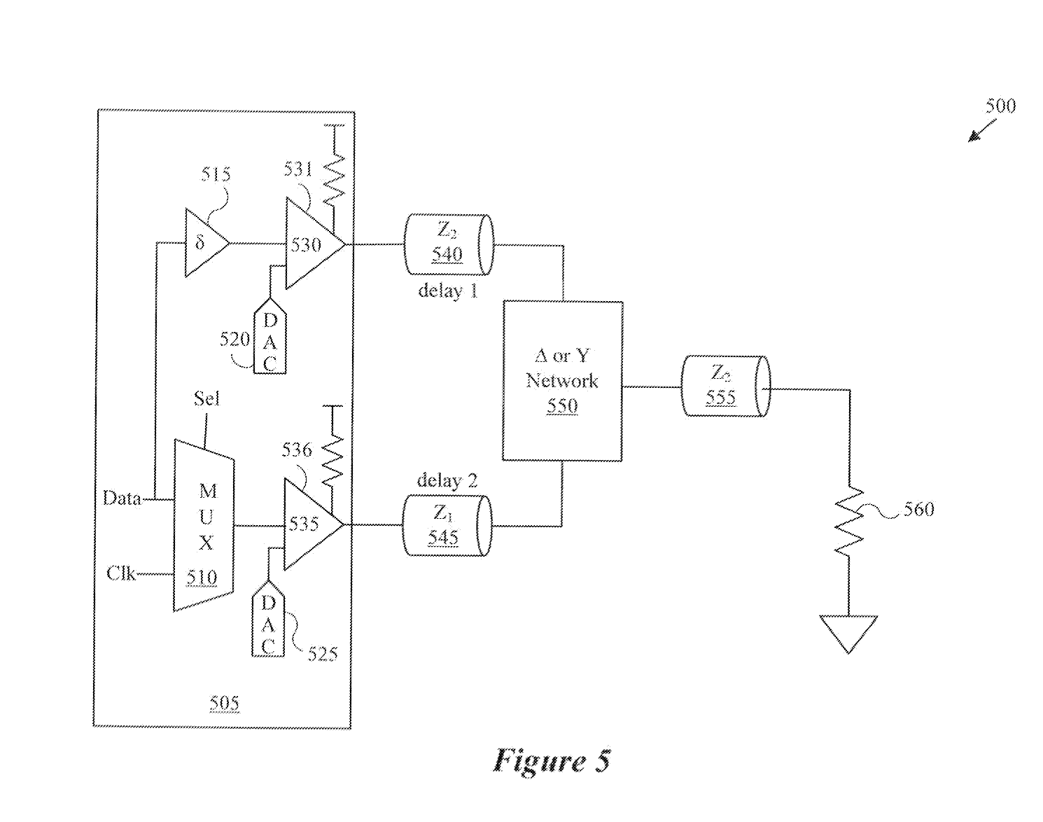

FIG. 5 illustrates an alternative embodiment 500 for generation of a two-pulse response. As shown in FIG. 5, rather than splitting an initial or input pulse from a single source, two sources are derived from an existing on board chip 505. The chip 505 preferably has a data signal port that is used for a first path and a clock signal port that is used for a second path. In one embodiment, an Ethernet type chip is used such as, for example, a 10G Ethernet chip.

As shown in FIG. 5, in the first path, the data signal is coupled to a delay element 515, which is coupled to an amplifier 530. The amplifier 530 is also coupled to a digital-to-analog converter 520 and a resistor 531. The output of the amplifier 530 is coupled to a combiner 550 through a segment 540 having an impedance Z1 and a Delay 1. The combiner 550 is preferably implemented by using a Δ or Y type network.

Also shown in FIG. 5, in the second path, the clock signal and the data signal are coupled to a multiplexor 510, which is coupled to an amplifier 535. The amplifier 535 is also coupled to a digital-to-analog converter 525 and a resistor 536. The output of the amplifier 535 is coupled to the combiner 550 through a segment 545 with an impedance Z1 and a Delay 2. The combiner 550 outputs to a load 560 through a segment 555 having an impedance Z2, thereby forming an output path.

The delays between the clock and data paths are preferably matched. Hence, the first (data) path preferably includes the delay element 515 configured to match the delay of the multiplexor 510 in the second (clock) path. In operation, the multiplexor 510 selects either a valid data signal or the clock signal to pass through to the amplifier 535. Also during operation, two pulses are generated by using the data and/or clock signals from the chip 505. The two pulses preferably arrive at the power combiner 550 at different times. The combiner 550 includes an interface that is configured such that the three segments 540, 545, and 555 (each having impedances Z1, Z1, and Z2 respectively) coupled thereto, are matched. In a particular embodiment, the three segments 540, 545, and 555 have impedances of about 50Ω each, and the load 560 also has an impedance of about 50Ω. Preferably, there are no reflections from the incident pulse, and forward-going pulses are launched from the combiner 550 in the direction of the output segment 555.

The configuration 500 of FIG. 5 further comprises an output node for combining together the first path, the second path, and the output path, and for transmitting a shaped electronic pulse, matched to the output path including the impedance of the output segment 555 and the load 560. As described above, in some embodiments, the output impedance is substantially equal to the impedances of the segments 540 and 545, of the first and second paths.

The desired pulse(s) are directed toward the load 560, and any undesired pulse returns towards the source in the opposite path where it is advantageously eliminated. The desired pulses from the two paths are appropriately spaced and/or delayed and have selected relative magnitudes, thereby generating a composite pulse or signal suitable for testing such as for stress testing of electronic components. Moreover, the shape in terms of amplitude of the test pulse is configurable. For instance, the magnitude of the voltage swing in each path is tunable via the independently controlled digital-to-analog converters (DACs) 520 and 525.

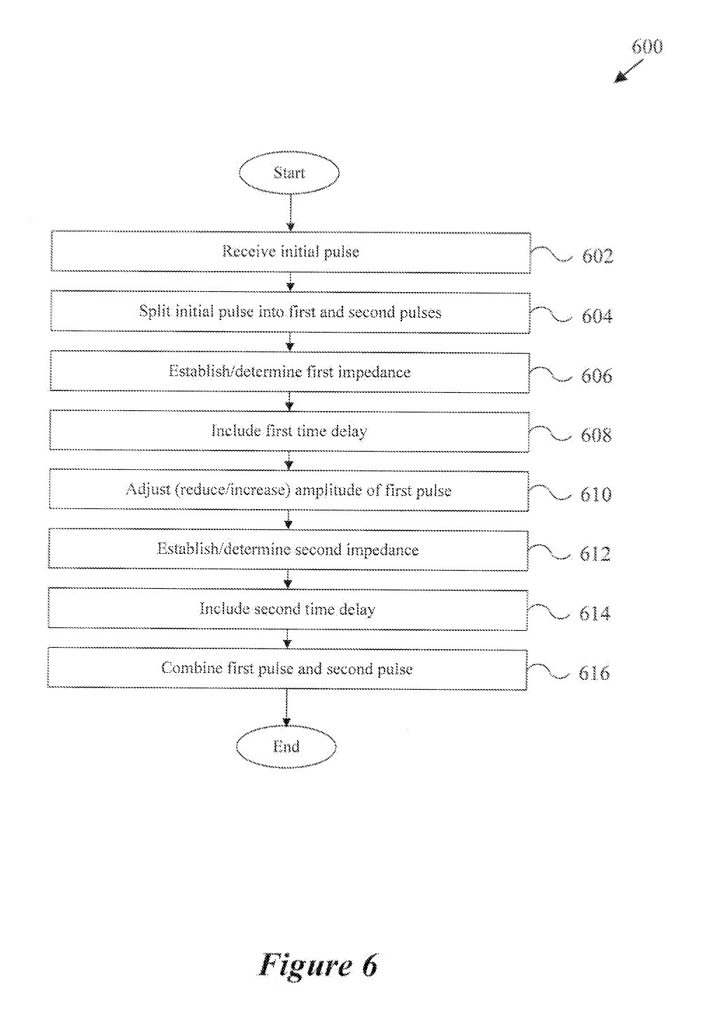

FIG. 6 illustrates a process 600 of shaping an electronic pulse. As shown in FIG. 6, the process 600 begins at the step 602, where an initial pulse is received. Then, the process 600 transitions to the step 604, where the initial pulse is split into a first pulse, such as for a first path, and into a second pulse, such as for a second path. Then, at the step 606, a first characteristic impedance is determined and/or established for the first path. Next, at the step 608, a first time delay is included and/or added to the first pulse of the first path. At the step 610, the amplitude of the first pulse may be adjusted, such as increased or reduced, for example. Some embodiments use a matched and/or passive attenuator that is matched to the first characteristic impedance to reduce the amplitude of the first pulse, relative to the second pulse.

Once the amplitude of the first pulse is optionally adjusted at the step 610, the process 600 transitions to the step 612, where a second characteristic impedance is established and/or determined such as for the second path. Then, at the step 614, a second time delay is included and/or added to the second pulse of the second path. Next, the first pulse and the second pulse are combined to form an output, at the step 616. After the step 616, the process 600 concludes.

One of ordinary skill recognizes that the order of the steps in the foregoing described process 600 is not intended to be limiting. For instance, the steps may be rearranged where the second characteristic impedance is established and/or determined before the first, and the like. Further, exemplary embodiments are described above for the purpose of illustration, but are not intended to limit the invention to the precise form described. In particular, it is contemplated that functional implementations described herein may be implemented equivalently in hardware, software, firmware, and/or other available functional components or materials. Other variations and embodiments are possible in light of above teachings, and it is thus intended that the scope of invention not be limited by this description.

Some of the embodiments described above eliminate the need for expensive, discrete high-speed amplifiers. Conventionally, such amplifiers of 5 GigaHertz or higher may be undesirably required for 10 Gigabit Ethernet signals. The described embodiments also eliminate the need for a disadvantageous tradeoff between mitigation of runt pulses and desired signal amplitude.

What is claimed is:

1. A system for generating a two-pulse response signal from an initial pulse signal, the system comprising:
a splitter for receiving the initial pulse signal at a first node and for splitting the initial pulse signal into a first pulse signal and a second pulse signal;
a first module, comprising a first impedance, coupled to the splitter, for receiving the first pulse signal and for introducing a first time delay to the first pulse signal to produce a delayed first pulse signal;
a first attenuator, coupled to the first module, for receiving the delayed first pulse signal and for generating an attenuated delayed first pulse signal;
a first resistive element, coupled to the first attenuator, for providing the attenuated delayed first pulse signal to a second node;
a second module, comprising a second impedance, coupled to the splitter, for receiving the second pulse signal and for introducing a second time delay to the second pulse signal to produce a delayed second pulse signal;
a second resistive element coupled to the first attenuator for providing the delayed second pulse signal to the second node; and
a combiner for combining the attenuated delayed first pulse signal with the delayed second pulse signal at the second node to generate the two-pulse response signal.

2. The system of claim 1, wherein the first attenuator comprises a passive attenuator that exhibits approximately equal bidirectional gain.

3. The system of claim 1, wherein the first attenuator is matched to the first impedance and second impedance.

4. The system of claim 1, wherein the system further comprises one or more of:
the first impedance is substantially equal to twice a source impedance; and
the second impedance is substantially equal to twice the source impedance.

5. The system of claim 1,
wherein a spacing of the two-pulse response signal is shaped by a difference between the first time delay and the second time delay.

6. The system of claim 1, wherein the first attenuator determines the relative amplitudes associated with the two-pulse response signal.

7. The system of claim 1, wherein a source impedance exhibited at the first node is approximately equal to an output impedance for the second node.

8. The system of claim 7, wherein:
the source impedance comprises approximately 50 ohms;
the first impedance comprises approximately 100 ohms;
the second impedance comprises approximately 100 ohms; and
an output impedance exhibited at the second node comprises approximately 50 ohms.

9. The system of claim 1, wherein:
the first resistive element comprises an impedance of about 62 ohms; and
the second resistive element comprises an impedance of about 62 ohms.

10. The system of claim 1, further comprising: a second attenuator, coupled between the second node and a resistive load.

11. The system of claim 1, wherein the first attenuator comprises a dynamic, programmable passive attenuator.

12. A system for artificial generation of stress test pulses with a two-pulse response signal, the system comprising:
an integrated circuit comprising a first source and a second source;
a first module, coupled to the first source, for establishing a first impedance and for introducing a first time delay in a first path;
a second module, coupled to the second source, for establishing a second impedance and for introducing a second time delay in a second path; and
a combiner node for combining together the first path and the second path into an output path, and for providing a shaped electronic pulse.

13. The system of claim 12, wherein the first source and the second source further for providing electronic pulses to the first path and the second path, wherein further:
the first source for providing a data signal;
a multiplexor, coupled to the second source, that selectively provides one of the data signal or a clock signal;
a delay element, coupled to the data signal, for matching the delay of the multiplexor in the second path such that delays between the first path and the second path are matched;
a first amplifier, coupled to the delay element;
a first digital-to-analog converter coupled to the first amplifier;
a first source resistor coupled to the first amplifier;
a second amplifier, coupled to the multiplexor;
a second tunable digital-to-analog converter coupled to the second amplifier; and
a second source resistor coupled to the second amplifier.

14. The system of claim 13, wherein the first and second digital-to-analog converters are independently controlled such that a magnitude of a voltage swing in the first and second paths are tunable.

15. The system of claim 13, wherein gain in the first and second paths, adjusted via the first and second digital-to-analog converters is software controlled.

16. The system of claim 13, wherein two peaks in a stress test pulse signal are separated by varying relative delays of the first and second paths.

17. The system of claim 13, wherein the first and second source resisters comprise approximately 50 ohms.

18. The system of claim 12, wherein impedances of each of the first path, the second path, and the output path are matched.

19. The system of claim 12, wherein the combiner node comprises a Delta resistive power combiner.

20. The system of claim 12, wherein the combiner node comprises a Y resistive power combiner.

21. The system of claim 12, wherein desired pulses from the first and second paths are delayed to generate a selected spacing shape for the two-pulse response signal.

22. The system of claim 12, wherein an attenuator controls relative magnitudes of pulse signals in the first and second paths to generate a selected amplitude shape for the two pulse response signal.

23. The system of claim 12, wherein any undesired returning pulses are terminated without affecting the two pulse response signal.

24. The system of claim 12, wherein the integrated circuit is configured for 10-G Ethernet communication.

25. The system of claim 12, wherein the first impedance for the first path comprises approximately 50 ohms.

26. The system of claim 12, wherein the second impedance for the second path comprises approximately 50 ohms.

27. The system of claim 12, wherein an output impedance for the output path comprises approximately 50 ohms.

28. A method of shaping an initial pulse signal, comprising:
splitting an initial pulse signal into a first pulse signal and a second pulse signal;
delaying the first pulse signal through a first impedance to generate a first delayed pulse signal;
attenuating the first delayed pulse signal to generate an attenuated first delayed pulse signal;
delaying the second pulse signal through a second impedance to generate a second delayed pulse signal; and
combining the attenuated first delayed pulse signal and the second delayed pulse signal.

29. The method of claim 28, the first impedance comprising a characteristic impedance for a first path, the second impedance comprising a characteristic impedance for a second path, wherein attenuating the first delayed pulse signal further comprises:
matching a passive attenuator to the first characteristic path impedance, the matched passive attenuator having approximately equal bidirectional gain.

30. The system of claim 29, further comprising:
coupling the output of the matched passive attenuator with a second node by using a first resistive element;
coupling the output of the second path with the second node by using a second resistive element;
combining the output of the first path and the output of the second path into a third output path at the second node; and
providing a shaped electronic pulse.

31. A system for shaping an electronic pulse, the system comprising:
means for splitting an initial pulse signal into a first pulse signal and a second pulse signal;
means for delaying the first pulse signal to generate a first delayed pulse signal;
means for attenuating the first delayed pulse signal to generate an attenuated first delayed pulse signal;
means for delaying the second pulse signal to generate a second delayed pulse signal; and
means for combining the attenuated first delayed pulse signal and the second delayed pulse signal.

32. The system of claim 31, wherein the means for delaying the first pulse signal comprises a first impedance within a first path having a first time delay, the first impedance comprising a characteristic impedance for the first path,
wherein the means for delaying the second pulse signal comprises a second impedance within a second path having a second time delay, the second impedance comprising a characteristic impedance for the second path,
wherein the means for attenuating the first delayed pulse signal further comprises:
a passive attenuator matched to the first characteristic path impedance, the matched passive attenuator having approximately equal bidirectional gain.

33. The system of claim 32, further comprising:
an output of the matched passive attenuator coupled with a second node by using a first resistive element;
an output of the second path coupled with the second node by using a second resistive element;
the second node configured such that the output of the first path and the output of the second path are combined together into a third output path that is configured to provide a shaped electronic pulse.
